(19) United States
(12) Patent Application Publication
(10) Pub. No.: US 2026/0004979 A1
(43) Pub. Date: Jan. 1, 2026

(54) HEAT DISSIPATION STRUCTURE FOR HIGH-CAPACITY CIRCUIT BREAKER

(71) Applicant: XI'AN JIAOTONG UNIVERSITY, Xi'an (CN)

(72) Inventors: Fei Yang, Xi'an (CN); Jinru Sun, Xi;an (CN); Zhaowei Diao, Xi'an (CN); Hexi Li, Xi'an (CN); Mingzhe Rong, Xi'an (CN); Yifei Wu, Xi'an (CN); Yi Wu, Xi'an (CN); Chunping Niu, Xi;an (CN); Yang Zhang, Xi;an (CN)

(21) Appl. No.: 19/250,688

(22) Filed: Jun. 26, 2025

(30) Foreign Application Priority Data
Jul. 1, 2024 (CN) 2024108883109

(51) Int. Cl. H01H 9/52; H01H 71/02; H05K 7/20

(52) U.S. Cl. CPC H01H 9/52; H01H 71/0207; H05K 7/20409; H05K 7/20436

(57) ABSTRACT

The present disclosure discloses a heat dissipation structure for a high-capacity circuit breaker, which includes: a circuit breaker body, inner heat dissipating fins, outer heat dissipating fins, and chimney cover plates; wherein the inner heat dissipating fins are disposed on an inner side of a base plate on an upper surface of a housing of the circuit breaker body, the outer heat dissipating fins are disposed on an outer side of the base plate on the upper surface of the housing of the circuit breaker body, and the outer heat dissipating fins are topped with the chimney cover plates. The inner and outer heat dissipating fins are arranged parallel to each other, are equidistantly distributed, and are perpendicular to the base plate. The chimney cover plates are made of epoxy resin and abut the top of the outer heat dissipating fins and are in parallel with the base plate.

### CROSS-REFERENCE TO RELATED APPLICATION

This application claims priority from the Chinese patent application 2024108683109 filed Jul. 1, 2024, the content of which is incorporated herein in the entirety by reference.

### TECHNICAL FIELD

The present disclosure belongs to the technical field of heat dissipation of circuit breakers, and particularly relates to the design of a heat dissipation structure for a high-capacity circuit breaker.

### BACKGROUND

With the rapid economic development in our country, the demand for electricity continues to increase, making the stability and excellent performance of electrical equipment increasingly necessary. As one of the most important components in the power system, circuit breakers are subject to higher performance requirements accordingly. As the voltage levels of the power grids laid out in our country rise and the capacity of circuit breakers continues to increase, their heat generation power also increases. The structure, materials, and external environment of circuit breakers often result in inadequate heat dissipation. If the temperature rise cannot be controlled, the temperature of each component of the circuit breaker will be too high, which will directly affect the operating performance of the circuit breaker, and may even lead to power accidents such as fire, seriously threatening the safety and reliability of power grid operation. For the design of high-capacity circuit breakers, reducing the temperature rise has become one of the key issues. However, as capacities continue to increase, conventional heat dissipation designs often fail to meet the heat dissipation requirements, the present disclosure designs a new structure on the basis of such.

The above information disclosed in the Background section is only for enhancement of understanding of the background of the disclosure and therefore may contain information that does not constitute the prior art that is well known to those of ordinary skill in the art.

### SUMMARY

An objective of the present disclosure is to provide a heat dissipation structure of a high-capacity circuit breaker, which is capable of significantly improving the heat dissipating capability of the circuit breaker without affecting the original function of the circuit breaker.

In order to achieve the above objective, the present disclosure discloses a heat dissipation structure of a large capacity circuit breaker, which includes: a circuit breaker body, inner heat dissipating fins, outer heat dissipating fins, and chimney cover plates; wherein the inner heat dissipating fins are disposed on an inner side of a base plate on an upper surface of a housing of the circuit breaker body, the outer heat dissipating fins are disposed on an outer side of the base plate on the upper surface of the housing of the circuit breaker body, and the outer heat dissipating fins are topped with the chimney cover plates.

Preferably, the inner and outer heat dissipating fins are made of aluminum, the inner heat dissipating fins are arranged parallel with the outer heat dissipating fins.

Preferably, the inner heat dissipating fins and the outer heat dissipating fins are perpendicular to the base plate of the circuit breaker body.

Preferably, the inner heat dissipating fins are equidistantly distributed and the size and number of the heat dissipating fins are able to be adjusted according to the size of the circuit breaker.

Preferably, the inner heat dissipating fins are connected to the outer heat dissipating fins and the inner and outer heat dissipating fins form a whole with the base plate of the circuit breaker body.

Preferably, the width of the chimney cover plate is about one sixth of the length of the outer heat dissipating fin.

Preferably, there are at least two chimney cover plates, which respectively abut outer edges on both sides of the top of the outer heat dissipation fins and are symmetrically arranged, and the chimney cover plates are parallel to the base plate of the circuit breaker body.

Preferably, the chimney cover plates are made of an epoxy resin material.

Preferably, the chimney cover plates are perpendicular to the outer heat dissipating fins.

Preferably, the size and material of the chimney cover plates are able to be adjusted according to circuit breaker specifications and temperature rise requirements.

Preferably, the chimney cover plates and the outer heat dissipating fins form a plurality of vent-like structures to achieve a chimney effect. According to the chimney effect, the chimney cover plates are added to the outer heat dissipating fins, and the high temperature air in the middle of the outer heat dissipating fins is discharged upward due to the high temperature and the low density, so that the air pressure in the middle of the outer heat dissipating fins becomes low, while the low temperature air at both sides of the circuit breaker can pass through the “chimney” consisting of the chimney cover plates and the outer heat dissipating fins and be squeezed into the middle of the outer heat dissipating fins with the low air pressure. At this point, the temperature difference between the low temperature air and the outer heat dissipating fins increases, creating a larger temperature gradient and accelerating the airflow between the heat dissipating fins. This, in turn, enables the temperature on the heat dissipating fins to drop faster, enhancing the heat dissipation capacity of the circuit breaker.

Preferably, the inner and outer heat dissipating fins are added based on the structure of the circuit breaker body to conduct the temperature of the air inside the circuit breaker from the inner heat dissipating fins to the outer heat dissipating fins by heat conduction, and the rectangular equidistant outer heat dissipating fins can increase the contact area with the outside air for faster cooling.

In the aforementioned technical solution, the heat dissipation structure for a high-capacity circuit breaker provided by this disclosure offers the following beneficial effects: this disclosure can effectively enhance the heat dissipation capacity of the circuit breaker. By utilizing the combination of the heat dissipating fins and chimney cover plates, it conducts heat from the inside of the circuit breaker and guides cold air into the heat dissipating fins, thus accelerating air flow and resulting in a rapid reduction in temperature rise. Moreover, this disclosure is implemented on the basis of the original main structure of the circuit breaker, without affecting the internal construction of the circuit breaker and without affecting the opening capability of the circuit breaker. More importantly, the materials used in the present disclosure are low in cost, and easily obtainable, with low construction difficulty. Additionally, it has no requirements for the external environment and can function in the face of a wide variety of environments.

### BRIEF DESCRIPTION OF DRAWINGS

FIG. 1 is an overall view of a heat dissipation structure and a housing of a high-capacity circuit breaker according to the present disclosure;

FIG. 2 is a cross-sectional view of a heat dissipation structure and a housing of a high-capacity circuit breaker according to the present disclosure;

FIG. 3 is a front view of a heat dissipation structure and a housing of a high-capacity circuit breaker according to the present disclosure;

FIG. 4 is a side view of a heat dissipation structure and a housing of a high-capacity circuit breaker according to the present disclosure; and

FIG. 5 is a schematic diagram of the principle of air flow direction due to the chimney effect according to the present disclosure.

Reference signs are as follows: 1—circuit breaker body, 2—inner heat dissipating fin, 3—outer heat dissipating fin, 4—chimney cover plate.

### DETAILED DESCRIPTION OF THE INVENTION

In order to more clearly describe the specific structure and contents of the present disclosure (a heat dissipation structure for a high-capacity circuit breaker), the following is a clear and complete description of the technical solution with reference to the drawings related to the embodiments, and it is obvious that the described embodiments are some embodiments of the present disclosure, but not all embodiments. As to the embodiments of the present disclosure, all other embodiments obtained by those skilled in the art without creative effort fall within the scope of protection of the present disclosure.

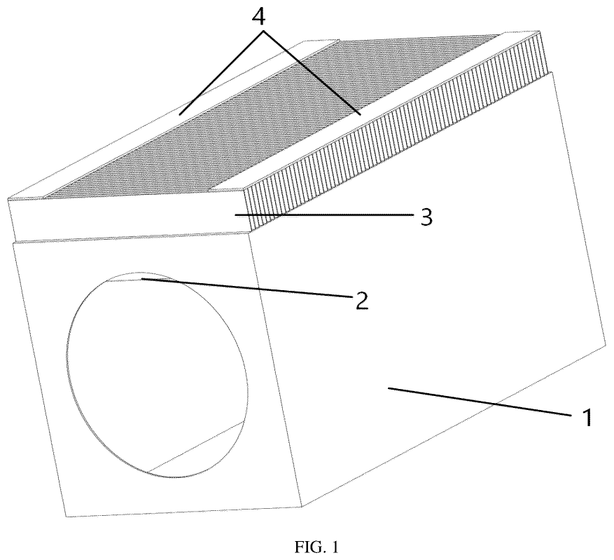

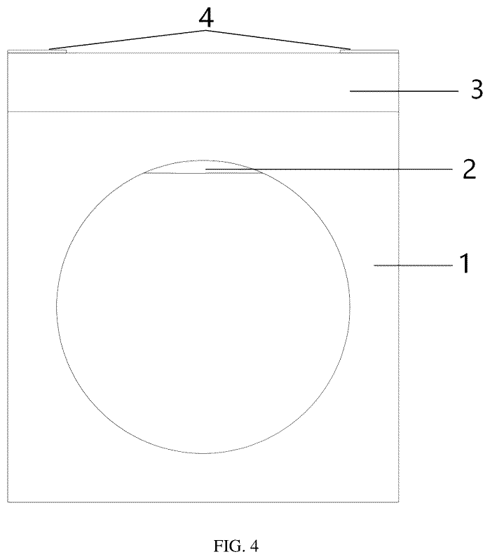

Accordingly, the following detailed description of the embodiments of the disclosure provided in FIGS. 1 to 5 is not intended to limit the scope of the claimed disclosure, but is merely to represent selected embodiments of the disclosure. Based on the embodiments of the present disclosure, all other embodiments obtained by those skilled in the art without creative work are within the scope of protection of the present disclosure.

It should be noted that like reference numerals and letters represent like items in the following figures, and therefore, once an item is defined in one figure, it need not be further defined and explained in the subsequent figures.

In the description of the disclosure, it needs to be understood that when the orientations or positional relationships shown by the terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, etc. are based on the orientations or positional relationships shown in the drawings, they are used only for convenience and simplification of the description, and do not indicate or imply that the referred device or element must have a specific orientation, be constructed and operated in a specific orientation, and therefore should not be construed as limitations on the present disclosure.

In addition, the terms “first” and “second” are used for descriptive purposes only, and cannot be understood to indicate or imply relative importance or to implicitly indicate the number of technical features indicated. Thus, a feature defined as “first” or “second” may explicitly or implicitly include one or more of the features. In the description of the present disclosure, “a plurality” means two or more unless specifically defined otherwise.

In the present disclosure, unless otherwise explicitly specified and limited, terms such as “mounted”, “connected”, “connection”, and “fixed” should be understood in a broad sense, for example, “connection” may be fixed connection or detachable connection or integrated connection, may be direct connection or indirect connection through an intermediate medium, and may be internal communication of two elements or the interaction of two elements. For those of ordinary skilled in the art, the specific meanings of the above terms in the present application may be understood according to specific situations.

In the present disclosure, unless expressly specified and defined otherwise, a first feature being “above” or “below” a second feature may include that the first and second features are in direct contact or that the first and second features are not in direct contact but are in contact through another feature between them. Moreover, the first feature being located at the “upper”, “above” and “on” the second feature includes that the first feature is located right above and at the oblique top of the second feature, or only shows that the horizontal height of the first feature is greater than that of the second feature; and the first feature being located at the “lower”, “below” and “under” the second feature includes that the first feature is located under and at the oblique bottom of the second feature, or only shows that the horizontal height of the first feature is smaller than that of the second feature.

In order for those skilled in the art to better understand the technical solutions of the present disclosure, the present disclosure will be further described in detail below with the accompanying drawings.

Referring to FIG. 1, the present disclosure provides a housing of a high-capacity circuit breaker, circular holes are opened at the centers of the front and rear surfaces of the housing, and the current direction is perpendicular to the direction of the circular holes. These circular holes are used for the protrusion of a main interrupting structure of the internal circuit breaker section, such as a conductive extension cylinder.

Referring to FIG. 1, the housing is taken as a body, the present disclosure also provides a heat dissipation structure for a high-capacity circuit breaker, including: a circuit breaker body 1, inner heat dissipating fins 2, outer heat dissipating fins 3, and chimney cover plates 4.

Wherein the specifications of the circuit breaker body 1 are not limited and can be adjusted depending on the size of the core interrupting structure in the circuit breaker or the heat dissipation structure requirements.

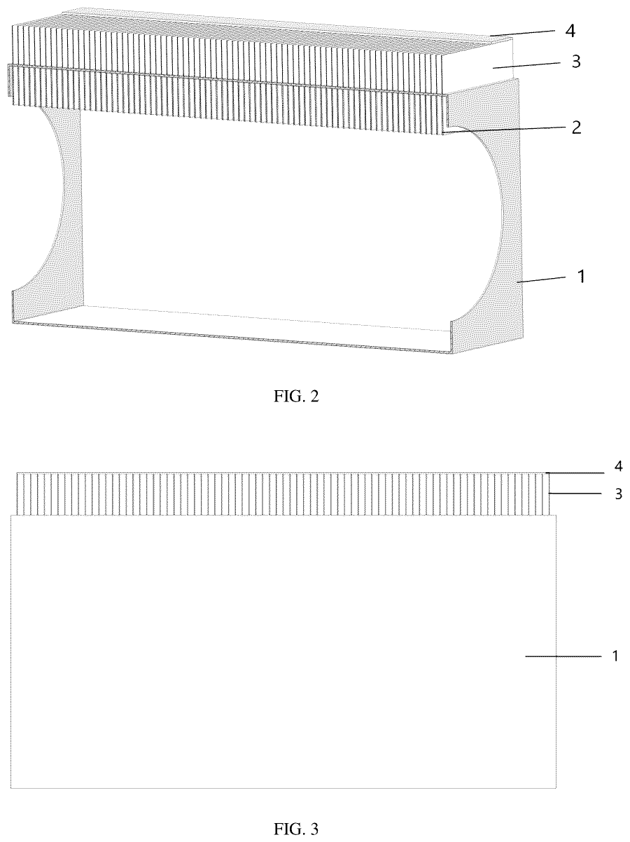

On the inner and outer sides of the base plate on the upper surface of the housing of the circuit breaker body, there are rows of heat dissipation fins, i.e., inner and outer heat dissipating fins, perpendicular to the base plate, as shown in FIG. 2. The heat dissipating fins are perpendicular to the current direction and have the same length as the width of the circuit breaker so that they cover the entire surface of the circuit breaker, the thickness of the heat dissipating fins is about 5-7 mm, the height of the heat dissipating fins is 200 mm, all of which can be adjusted according to the circuit breaker specifications. The inner and outer heat dissipating fins are equidistantly distributed to facilitate manufacturing. The spacing between each two heat dissipating fins is comparable to or slightly wider than the thickness of the heat dissipating fins, leaving sufficient space between the heat dissipating fins for air to flow, and further advantageously reducing temperature rise.

Referring to FIG. 1, there are two chimney cover plates 4 on both sides of the top of the outer heat dissipating fins 3, the chimney cover plates 4 abut the top of the outer heat dissipating fins 3, face perpendicular to the outer heat dissipating fins 3, and are parallel to the base plate on the upper surface of the housing of the breaker body. The length of the chimney cover plates should be the same as the length of the housing of the circuit breaker to cover all the heat dissipation fins. The width of the cover plates should be appropriately set, it should not be too wide to hinder the upward exhaust of hot air from the middle, nor too narrow to impair the chimney effect of the chimney cover plates. Research has found that a width of approximately one-sixth of the length of the heat dissipation fins for each chimney cover plate yields optimal results. The specific dimensions can be set according to actual engineering requirements.

In one embodiment, the heat dissipation fins are made of aluminum or aluminum alloy having excellent thermal conductivity.

In one embodiment, the chimney cover plates are made of an epoxy resin material. As a good organic solvent, epoxy resin can be doped with other substances to alter its properties. Additionally, due to its insulating property, it can avoid affecting the magnetic field of the entire circuit breaker. Furthermore, the material and size of the cover plates can be adjusted subsequently according to heat dissipation requirements and construction specifications.

In the above embodiments, the inner heat dissipation fins can increase their contact arca with the high-temperature air inside the circuit breaker, enhancing the absorption of internal temperature by the inner heat dissipation fins and the base plate. This allows more heat to be transferred from the inside of the circuit breaker through the inner heat dissipation fins to the base plate on the top of the housing, increasing the speed of heat transfer from the inside to the outside. The outer heat dissipation fins increase the contact between the circuit breaker and the external air, enabling the temperature on the base plate to be transferred to the external air more quickly. This accelerates the speed of heat conduction of the overall temperature of the circuit breaker to the outside through the outer heat dissipation fins. Therefore, the presence of both inner and outer heat dissipation fins can significantly improve the heat dissipation capacity of the circuit breaker.

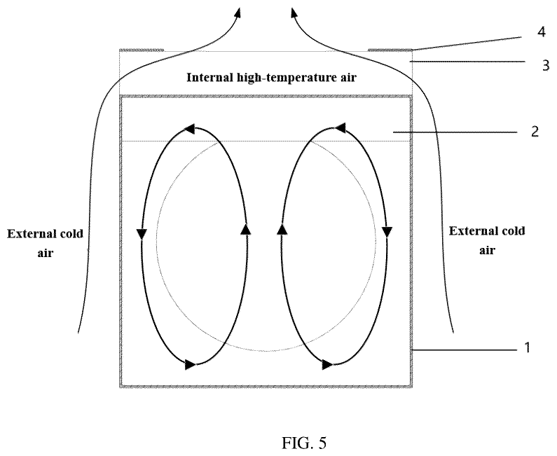

In one embodiment, as shown in FIG. 5, which is a schematic diagram of the function of the chimney cover plates, the convection of air can be enhanced by adding the chimney cover plates to the outer heat dissipating fins, corresponding to creating a plurality of air passages between the chimney cover plates, the outer heat dissipating fins and the base plate, according to the chimney effect. When the circuit breaker is in operation, the temperature of the entire base plate rises, causing the air to ascend due to the decreased density of hot air as it approaches the warmer area near the circuit breaker. However, the hot air on both sides of the heat dissipating fins, obstructed by the chimney cover plates, cannot flow upward smoothly, while the hot air in the middle of the outer heat dissipating fins, being less dense due to its higher temperature, flows upward. This results in a lower air pressure in the middle of the base plate of the circuit breaker compared to its sides, and the low temperature air on both sides is squeezed through the air channels, or the “chimney”, formed by the chimney cover plates and the heat dissipating fins, into the middle of the heat dissipating fins where the air pressure is lower. At this point, the air pressure of the low temperature air, i.e., the external cold air, on both sides of the circuit breaker will be higher than the air pressure within the “chimney”, and this pressure difference accelerates the inflow of external air into the chimney. The accelerated inflow of air, due to its lower temperature, increases the temperature difference with the base plates and heat dissipating fins, thus forming a larger temperature gradient. An increased temperature gradient accelerates the rate of heat conduction from the heat dissipating fins and base plates to the air, thereby achieving the effect of accelerating heat dissipation of the circuit breaker and reducing temperature rise. Additionally, increasing the airflow velocity between the heat dissipating fins also causes the temperature of the heat dissipating fins to decrease more rapidly, enhancing the heat dissipation capability of the circuit breaker.

A circuit breaker refers to a switching device that is capable of switching on, carrying, and interrupting currents under normal loop conditions and switching on, carrying, and interrupting currents under abnormal loop conditions for a specified period of time. As a crucial component in the power system, the reliability of a circuit breaker determines the health and safety of the entire power system. Excessive temperature rise in a circuit breaker can lead to shortened lifespan and aging of internal components. If the temperature rise is not controlled over a long period, it may directly affect the interrupting capacity of the circuit breaker and potentially cause faults such as leakage and short circuits. In the above embodiments, it can be seen that the present disclosure enhances the ability of the circuit breaker to reduce temperature rise by adding the heat dissipation fins and chimney cover plates, thereby significantly improving the reliability of the circuit breaker and, consequently, the reliability of the entire power system.

Finally, it should be noted that the described embodiments are only some but not all of the embodiments of the present application, and all other embodiments obtained by those skilled in the art without making inventive step on the basis of the embodiments of the present application are within the scope of the present application.

While certain exemplary embodiments of the present disclosure have been described above by way of illustration only, it will be appreciated that those skilled in the art will be able to modify the described embodiments in various ways without departing from the spirit and scope of the present disclosure. Accordingly, the foregoing drawings and description are illustrative in nature and should not be construed as limiting the scope of the disclosure as claimed.

1. A heat dissipation structure for a high-capacity circuit breaker, comprising: a circuit breaker body, inner heat dissipating fins, outer heat dissipating fins, and chimney cover plates; wherein the inner heat dissipating fins are disposed on an inner side of a base plate on an upper surface of a housing of the circuit breaker body, the outer heat dissipating fins are disposed on an outer side of the base plate on the upper surface of the housing of the circuit breaker body, and the outer heat dissipating fins are topped with the chimney cover plates.

2. The heat dissipation structure for a high-capacity circuit breaker according to claim 1, wherein the inner heat dissipating fins are preferably arranged in parallel with the outer heat dissipating fins.

3. The heat dissipation structure for a high-capacity circuit breaker according to claim 1, wherein the inner heat dissipating fins and the outer heat dissipating fins are perpendicular to the base plate of the circuit breaker body.

4. The heat dissipation structure for a high-capacity circuit breaker according to claim 1, wherein the inner heat dissipating fins are equidistantly distributed and the size and number of the heat dissipating fins are able to be adjusted according to the size of the circuit breaker.

5. The heat dissipation structure for a high-capacity circuit breaker according to claim 1, wherein the inner heat dissipating fins are connected to the outer heat dissipating fins.

6. The heat dissipation structure for a high-capacity circuit breaker according to claim 1, wherein the width of the chimney cover plate is about one sixth of the length of the outer heat dissipating fin.

7. The heat dissipation structure for a high-capacity circuit breaker according to claim 1, wherein there are at least two chimney cover plates, which respectively abut outer edges on both sides of the top of the outer heat dissipation fins and are parallel to the base plate of the circuit breaker body.

8. The heat dissipation structure for a high-capacity circuit breaker according to claim 1, wherein the chimney cover plates are symmetrically arranged.

9. The heat dissipation structure for a high-capacity circuit breaker according to claim 1, wherein the chimney cover plates are perpendicular to the outer heat dissipating fins.

10. The heat dissipation structure for a high-capacity circuit breaker according to claim 1, wherein the chimney cover plates and the outer heat dissipating fins form a plurality of vent-like structures to achieve a chimney effect.
